(19) United States
(12) Patent Application Publication
(10) Pub. No.: US 2019/0096711 A1
(43) Pub. Date: Mar. 28, 2019

(54) SUBSTRATE PROCESSING APPARATUS AND SUBSTRATE PROCESSING METHOD

(71) Applicant: Tokyo Electron Limited, Tokyo (JP)

(72) Inventors: Hiroki Ohno, Tokyo (JP); Hideaki Sato, Koshi City (JP); Takao Inada, Koshi City (JP); Hisashi Kawano, Koshi City (JP); Yoshinori Nishiwaki, Tokyo (JP); Takahiko Otsu, Koshi City (JP)

(21) Appl. No.: 16/144,016

(22) Filed: Sep. 27, 2018

(30) Foreign Application Priority Data
Sep. 28, 2017 (JP) 2017-188533

(51) Int. Cl. H01L 21/67; H01L 21/311

(52) U.S. Cl. CPC H01L 21/67086; H01L 21/67253; H01L 21/31111

(57) ABSTRACT

A substrate processing apparatus and a substrate processing method capable of suppressing precipitation of a silicon oxide while improving selectivity for etching a silicon nitride film are provided. The substrate processing apparatus includes a substrate processing tub, a phosphoric acid processing liquid supply unit, a circulation path, a SiO₂ precipitation inhibitor supply unit and a mixing unit. The phosphoric acid processing liquid supply unit is configured to supply a phosphoric acid processing liquid used in performing an etching processing in the substrate processing tub. The circulation path is configured to circulate the phosphoric acid processing liquid supplied into the substrate processing tub. The SiO₂ precipitation inhibitor supply unit is configured to supply a SiO₂ precipitation inhibitor into the circulation path. The mixing unit is configured to mix a silicon-containing compound into the phosphoric acid processing liquid before the phosphoric acid processing liquid is supplied into the circulation path.

### CROSS-REFERENCE TO RELATED APPLICATION

This application claims the benefit of Japanese Patent Application No. 2017-188533 filed on Sep. 28, 2017, the entire disclosures of which are incorporated herein by reference.

### TECHNICAL FIELD

The various aspects and embodiments described herein pertain generally to a substrate processing apparatus and a substrate processing method.

### BACKGROUND

Conventionally, in a substrate processing apparatus, there is known an etching processing of selectively etching, between a silicon nitride film (SiN) and a silicon oxide film (SiO₂) formed on a substrate, the silicon nitride film by immersing the substrate in a phosphoric acid processing liquid (see Patent Document 1).

In this etching processing, it is known that selectivity for etching the silicon nitride film is improved if a silicon concentration of the phosphoric acid processing liquid is increased. Meanwhile, it is also known that if the silicon concentration of the phosphoric acid processing liquid is too high, a silicon oxide (SiO₂) is precipitated on the silicon oxide film.

For this reason, in the substrate processing apparatus, the silicon concentration of the phosphoric acid processing liquid is adjusted to fall within a constant range.
Patent Document 1: Japanese Patent Laid-open Publication No. 2013-232593

### SUMMARY

In the aforementioned substrate processing apparatus, however, there is still a room for improvement in that the precipitation of the silicon oxide needs to be suppressed while improving the selectivity for etching the silicon nitride film.

In view of the foregoing, exemplary embodiments provide a substrate processing apparatus and a substrate processing method capable of suppressing precipitation of a silicon oxide while improving selectivity for etching a silicon nitride film.

In one exemplary embodiment, a substrate processing apparatus includes a substrate processing tub, a phosphoric acid processing liquid supply unit, a circulation path, a SiO₂ precipitation inhibitor supply unit and a mixing unit. The phosphoric acid processing liquid supply unit is configured to supply a phosphoric acid processing liquid used in performing an etching processing in the substrate processing tub. The circulation path is configured to circulate the phosphoric acid processing liquid supplied into the substrate processing tub. The SiO₂ precipitation inhibitor supply unit is configured to supply a SiO₂ precipitation inhibitor into the circulation path. The mixing unit is configured to mix a silicon-containing compound into the phosphoric acid processing liquid before the phosphoric acid processing liquid is supplied into the circulation path.

According to the exemplary embodiments, it is possible to suppress the precipitation of the silicon oxide while improving the selectivity for etching the silicon nitride film.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view of a substrate processing apparatus;

FIG. 2 is a schematic block diagram illustrating a configuration of a processing tub for etching in accordance with a first exemplary embodiment;

FIG. 3 is a flowchart for describing a method of supplying a SiO₂ precipitation inhibitor in accordance with the first exemplary embodiment;

FIG. 4 is a schematic block diagram illustrating a processing tub for etching in accordance with a second exemplary embodiment;

FIG. 5 is a flowchart for describing a method of supplying a SiO₂ precipitation inhibitor in accordance with the second exemplary embodiment;

FIG. 6 is a schematic block diagram illustrating a processing tub for etching in accordance with a third exemplary embodiment;

FIG. 7 is a cross sectional view illustrating a schematic configuration of a mixer in accordance with a third exemplary embodiment;

FIG. 8 is a flowchart for describing a method of supplying a SiO₂ precipitation inhibitor in accordance with a third exemplary embodiment;

FIG. 9 is a schematic block diagram illustrating a processing tub for etching in accordance with a fourth exemplary embodiment;

FIG. 10 is a cross sectional view illustrating a schematic configuration of a mixer in accordance with the fourth exemplary embodiment; and

FIG. 11 is a flowchart for describing a method of supplying a SiO₂ precipitation inhibitor in accordance with the fourth exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a substrate processing apparatus and a substrate processing method according to exemplary embodiments will be described in detail with reference to the accompanying drawings. Here, however, it should be noted that the exemplary embodiments are not limiting.

### First Exemplary Embodiment

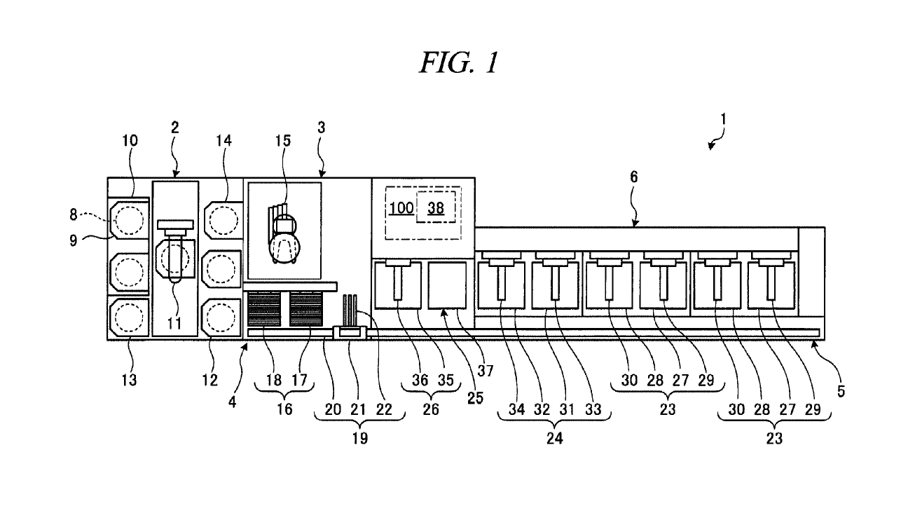

As depicted in FIG. 1, a substrate processing apparatus 1 according to a first exemplary embodiment includes a carrier carry-in/out unit 2, a lot forming unit 3, a lot placing unit 4, a lot transferring unit 5, a lot processing unit 6 and a control unit 100. FIG. 1 is a schematic plan view of the substrate processing apparatus 1. Here, a direction orthogonal to a horizontal direction will be defined as a vertical direction.

The carrier carry-in/out unit 2 is configured to perform a carry-in and a carry-out of a carrier 9 in which a plurality (e.g., 25 sheets) of substrates (silicon wafers) 8 are vertically arranged in a horizontal posture.

The carrier carry-in/out unit 2 is equipped with a carrier stage 10 configured to place multiple carriers 9 thereon; a carrier transfer device 11 configured to transfer the carrier 9; carrier stocks 12 and 13 configured to place therein the carrier 9 temporarily; and a carrier placing table 14 configured to place the carrier 9 thereon.

The carrier carry-in/out unit 2 transfers the carrier 9, which is carried onto the carrier stage 10 from the outside, to the carrier stock 12 or the carrier placing table 14 by using the carrier transfer device 11. That is, the carrier carry-in/out unit 2 transfers the carrier 9 accommodating therein the plurality of substrates 8 before being processed by the lot processing unit 6 to the carrier stock 12 or the carrier placing table 14.

The carrier stock 12 temporarily places therein the carrier 9 which accommodates therein the plurality of substrates 8 before being processed by the lot processing unit 6.

The plurality of substrates 8 are carried out from the carrier 9, which is carried onto the carrier placing table 14 while accommodating therein the plurality of substrates 8 before being processed by the lot processing unit 6, by a substrate transfer device 15 to be described later.

Further, the plurality of substrates 8 after being processed by the lot processing unit 6 is carried from the substrate transfer device 15 into the carrier 9 which is placed on the carrier placing table 14 and does not accommodate the substrates 8 therein.

The carrier carry-in/out unit 2 carries the carrier 9, which is placed on the carrier placing table 14 and accommodates therein the plurality of substrates 8 after being processed by the lot processing unit 6, to the carrier stock 13 or the carrier stage 10 by using the carrier transfer device 11.

The carrier stock 13 temporarily accommodates therein the plurality of substrates 8 after being processed by the lot processing unit 6. The carrier 9 transferred to the carrier stage 10 is carried to the outside.

The lot forming unit 3 is equipped with the substrate transfer device 15 configured to transfer a plurality (e.g., 25 sheets) of substrates 8. The lot forming unit 3 performs a transfer of the plurality (e.g., 25 sheets) of substrates 8 by the substrate transfer device 15 twice and forms a lot composed of a multiplicity (e.g., 50 sheets) of substrates 8.

The lot forming unit 3 forms the lot by transferring the multiplicity of substrates 8 from the carriers 9 placed on the carrier placing table 14 to the lot placing unit 4 by using the carrier transfer device 15 and placing the multiplicity of substrates 8 on the lot placing unit 4.

The multiplicity of substrates 8 belonging to the single lot are processed by the lot processing unit 6 at the same time. When forming the lot, the substrates 8 may be arranged such that surfaces thereof having patterns formed thereon face each other or such that the surfaces thereof having the patterns formed thereon all face to one direction.

Further, in the lot forming unit 3, the multiplicity of substrates 8 are transferred by the substrate transfer device 15 to the carrier 9 from the lot placed in the lot placing unit 4 after being subjected to the processing in the lot processing unit 6.

The substrate transfer device 15 is equipped with, as a substrate supporting unit configured to support the multiplicity of substrates 8, two types of substrate supporting unit: a before-processed substrate supporting unit (not shown) configured to support the substrates 8 before being subjected to a processing; and an after-processed substrate supporting unit (not shown) configured to support the processed substrates 8. Accordingly, particles or the like adhering to the substrates 8 before being processed may be suppressed from adhering to the substrates 8 after being processed.

The substrate transfer device 15 changes a posture of the substrates 8 from a horizontal posture to a vertical posture and from the vertical posture to the horizontal posture while transferring the substrates 8.

In the lot placing unit 4, the lot which is transferred between the lot forming unit 3 and the lot processing unit 6 by the lot transferring unit 5 is temporarily placed (stands by) on the lot placing table 16.

The lot placing unit 4 is equipped with a carry-in side lot placing table 17 and a carry-out side lot placing table 18.

The carry-in side lot placing table 17 is configured to place thereon the lot before being processed. The carry-out side lot placing table 18 is configured to place thereon the lot after being processed.

On each of the carry-in side lot placing table 17 and the carry-out side lot placing table 18, the multiplicity of substrates 8 corresponding to the single lot are arranged in a forward-backward direction with the vertical posture.

The lot transferring unit 5 is configured to transfer the lot between the lot placing unit 4 and the lot processing unit 6 and within the lot processing unit 6.

The lot transferring unit 5 is equipped with the lot transfer device 19 configured to transfer the lot. The lot transfer device 19 includes a rail 20 extended along the lot placing unit 4 and the lot processing unit 6; and a moving body 21 configured to be moved along the rail 20 while holding the lot.

The moving body 21 is provided with a substrate holding body 22 configured to hold the multiplicity of substrates 8 arranged in the forward-backward direction with the vertical posture.

The lot transferring unit 5 receives the lot placed on the carry-in side lot placing table 17 with the substrate holding body 22 of the lot transfer device 19 and delivers the received lot to the lot processing unit 6.

Further, the lot transferring unit 5 receives the lot processed by the lot processing unit 6 with the substrate holding body 22 of the lot transfer device 19 and delivers the received lot to the carry-out side lot placing table 18.

Further, the lot transferring unit 5 also performs the transfer of the lot within the lot processing unit 6 by using the lot transfer device 19.

The lot processing unit 6 is configured to perform a processing such as etching, cleaning and drying on the single lot composed of the multiplicity of substrates 8 arranged in the forward-backward direction with the vertical posture.

The lot processing unit 6 includes two etching apparatuses 23 configured to perform an etching processing on the lot; a cleaning apparatus 24 configured to perform a cleaning processing on the lot; a substrate holding body cleaning apparatus 25 configured to perform a cleaning processing on the substrate holding body 22; and a drying apparatus 26 configured to perform a drying processing on the lot. Further, the number of the etching apparatuses 23 is not limited to 2 and may be one or more than 2.

Each etching apparatus 23 includes a processing tub 27 for etching, a processing tub 28 for rinsing, and substrate elevating devices 29 and 30.

The processing tub 27 for etching stores therein a processing liquid for etching (hereinafter, referred to as “etching liquid”). The processing tub 28 for rinsing stores therein a processing liquid for rinsing (pure water or the like). Details of the processing tub 27 for etching will be described later.

The multiple number of substrates 8 constituting the single lot are held by the substrate elevating device 29 (30) while being arranged in the forward-backward direction with the vertical posture.

The etching apparatus 23 receives the lot from the substrate holding body 22 of the lot transfer device 19 with the substrate elevating device 29, and the received lot is moved up and down by the substrate elevating device 29. Accordingly, the lot is immersed in the etching liquid in the processing tub 27, so that an etching processing is performed.

Thereafter, the etching apparatus 23 takes out the lot from the processing tub 27 by raising the substrate elevating device 29, and delivers the lot to the substrate holding body 22 of the lot transfer device 19 from the substrate elevating device 29.

Then, the lot is received by the substrate elevating device 30 from the substrate holding body 22 of the lot transfer device 19, and the received lot is moved up and down by the substrate elevating device 30. Accordingly, the lot is immersed in the processing liquid for rinsing in the processing tub 28, so that a rinsing processing is performed.

Thereafter, the etching apparatus 23 takes out the lot from the processing tub 28 by raising the substrate elevating device 30, and delivers the lot to the substrate holding body 22 of the lot transfer device 19 from the substrate elevating device 30.

The cleaning apparatus 24 is equipped with a processing tub 31 for cleaning, a processing tub 32 for rinsing, and substrate elevating devices 33 and 34.

The processing tub 31 for cleaning stores therein a processing liquid for cleaning (SC-1 or the like). The processing tub 32 for rinsing stores therein a processing liquid for rinsing (pure water or the like). The multiplicity of substrates 8 belonging to the single lot are held by each of the substrate elevating devices 33 and 34 while being arranged in the forward-backward direction with the vertical posture.

The drying apparatus 26 is equipped with a processing tub 35 and a substrate elevating device 36 configured to be moved up and down with respect to the processing tub 35.

A processing gas for drying (isopropyl alcohol) is supplied into the processing tub 35. The multiplicity of substrates 8 corresponding to the single lot are held by the substrate elevating device 36 while being arranged in the forward-backward direction with the vertical posture.

The drying apparatus 26 receives the lot from the substrate holding body 22 of the lot transfer device 19 with the substrate elevating device 36, and carries the received lot into the processing tub 35 by moving the receive lot up and down with the substrate elevating device 36. Then, a drying processing is performed on the lot by the processing gas for drying supplied into the processing tub 35. Thereafter, the drying apparatus 26 raises the lot with the substrate elevating device 36 and delivers the lot after being subject to the drying processing to the substrate holding body 22 of the lot transfer device 19 from the subtract elevating device 36.

The substrate holding body cleaning apparatus 25 includes a processing tub 37 and is configured to supply a processing liquid for cleaning and a drying gas into this processing tub 37. By supplying the drying gas after supplying the processing liquid for cleaning to the substrate holding body 22 of the lot transfer device 19, the substrate holding body cleaning apparatus 25 performs a cleaning processing on the substrate holding body 22.

The control unit 100 controls operations of individual components (the carrier carry-in/out unit 2, the lot forming unit 3, the lot placing unit 4, the lot transferring unit 5, and the lot processing unit 6) of the substrate processing apparatus 1. The control unit 100 controls the operations of the individual components of the substrate processing apparatus 1 based on signals from switches or the like.

The control unit 100 may be implemented by, for example, a computer and has a computer-readable recording medium 38. The recording medium 38 stores therein programs for controlling various types of processings performed in the substrate processing apparatus 1.

The control unit 100 controls the operation of the substrate processing apparatus 1 by reading and executing the programs stored in the recording medium 38. Further, the programs are stored in the compute-readable recording medium 38 and may be installed to the recording medium 38 of the control unit 100 from another recording medium.

The computer-readable recording medium 38 may be implemented by, by way of non-limiting example, a hard disk HD, a flexible disk FD, a compact disk CD, a magnet optical disk MO, a memory card, or the like.

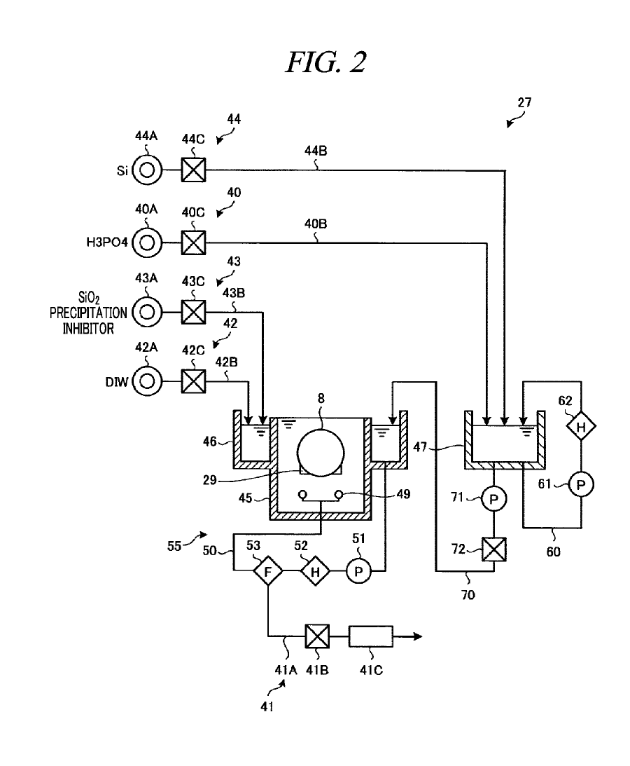

Now, the processing tub 27 for etching will be elaborated with reference to FIG. 2. FIG. 2 is a schematic block diagram illustrating a configuration of the processing tub 27 for etching according to the first exemplary embodiment.

In the processing tub 27 for etching, between a nitride film (SiN) and an oxide film (SiO₂) formed on the substrate 8, only the nitride film is selectively etched by using an etching liquid.

In the etching processing for the nitride film, a solution, prepared by adding a silicon (Si)-containing compound to a phosphoric acid (H₃PO₄) aqueous solution, with an adjusted silicon concentration is generally used as the etching liquid. As a way to adjust the silicon concentration, a method of dissolving silicon by immersing a dummy substrate in a phosphoric acid aqueous solution (seasoning), a method of dissolving a silicon-containing compound such as colloidal silica in the phosphoric acid aqueous solution, or the like may be used. Further, there is also employed a method of adjusting the silicon concentration by adding a silicon-containing compound aqueous solution to the phosphoric acid aqueous solution. Here, it is desirable that the aforementioned silicon-containing compound may at least contain, besides the silicon, carbon, oxygen, nitrogen and hydrogen.

In the etching processing, by increasing the silicon concentration of the etching liquid, selectivity for etching only the nitride film can be improved. If, however, the silicon concentration of the etching liquid is increased excessively as the nitride film is dissolved in the etching liquid through the etching processing, the silicon dissolved in the etching liquid may be precipitated on the oxide film as a silicon oxide.

In the present exemplary embodiment, to suppress the precipitation of the silicon oxide, the etching processing is performed by using an etching liquid prepared by adding the SiO₂ precipitation inhibitor to the phosphoric acid aqueous solution mixed with the silicon-containing compound aqueous solution.

The SiO₂ precipitation inhibitor is not particularly limited as long as it contains a component capable of suppressing precipitation of a silicon oxide by stabilizing silicon ions dissolved in the phosphoric acid aqueous solution in a dissolved state. By way of example, a hexafluorosilicic acid (H₂SiF₆) aqueous solution containing a fluorine component may be used. Here, an additive such as ammonia may be added to stabilize hexafluorosilicic acid in the aqueous solution.

The SiO₂ precipitation inhibitor may be implemented by, by way of non-limiting example, ammonium hexafluorosilicate ((NH₄)₂SiF₆), sodium hexafluorosilicate (Na₂SiF₆), or the like.

The processing tub 27 for etching is equipped with a phosphoric acid aqueous solution supply unit 40, a phosphoric acid aqueous solution drain unit 41, a pure water supply unit 42, a SiO₂ precipitation inhibitor supply unit 43, a silicon supply unit 44, an inner tub 45, an outer tub 46 and a temperature control tank 47.

The phosphoric acid aqueous solution supply unit 40 includes a phosphoric acid aqueous solution source 40A, a phosphoric acid aqueous solution supply line 40B and a first flow rate controller 40C. The phosphoric acid aqueous solution supply unit 40 constitutes a phosphoric acid processing liquid supply unit. The phosphoric acid aqueous solution supply line 40B constitutes a phosphoric acid processing liquid supply line.

The phosphoric acid aqueous solution source 40A is a tank configured to store the phosphoric acid aqueous solution therein. The phosphoric acid aqueous solution supply line 40B is configured to connect the phosphoric acid aqueous solution source 40A and the temperature control tank 47 and configured to supply the phosphoric acid aqueous solution from the phosphoric acid aqueous solution source 40A to the temperature control tank 47.

The first flow rate controller 40C is provided at the phosphoric acid aqueous solution supply line 40B and configured to adjust a flow rate of the phosphoric acid aqueous solution supplied to the temperature control tank 47. The first flow rate controller 40C may be composed of an opening/closing valve, a flow rate control valve, a flowmeter, and so forth.

The pure water supply unit 42 includes a pure water source 42A, a pure water supply line 42B, and a second flow rate controller 42C. The pure water supply unit 42 is configured to supply pure water (DIW) into the outer tub 46 to replenish moisture that has evaporated as the etching liquid is heated.

The pure water supply line 42B is configured to connect the pure water source 42A and the outer tub 46 and configured to supply the pure water of a preset temperature from the pure water source 42A into the outer tub 46.

The second flow rate controller 42C is provided at the pure water supply line 42B and configured to adjust a flow rate of the pure water supplied to the outer tub 46. The second flow rate controller 42C is composed of an opening/closing valve, a flow rate control valve, a flowmeter, and so forth.

The SiO₂ precipitation inhibitor supply unit 43 includes a SiO₂ precipitation inhibitor source 43A, a SiO₂ precipitation inhibitor supply line 43B, and a third flow rate controller 43C. The SiO₂ precipitation inhibitor supply unit 43 is configured to supply the SiO₂ precipitation inhibitor into the outer tub 46 when performing the etching processing. Further, the SiO₂ precipitation inhibitor supply unit 43 is configured to supply the SiO₂ precipitation inhibitor into the outer tub 46 to replenish the SiO₂ precipitation inhibitor that has evaporated as the etching liquid is heated.

The SiO₂ precipitation inhibitor source 43A is a tank which stores the SiO₂ precipitation inhibitor therein. The SiO₂ precipitation inhibitor supply line 43B is configured to connect the SiO₂ precipitation inhibitor source 43A and the outer tub 46 and configured to supply the SiO₂ precipitation inhibitor from the SiO₂ precipitation inhibitor source 43A into the outer tub 46.

The third flow rate controller 43C is provided at the SiO₂ precipitation inhibitor supply line 43B and configured to adjust a flow rate of the SiO₂ precipitation inhibitor supplied to the outer tub 46. The third flow rate controller 43C is composed of an opening/closing valve, a flow rate control valve, a flowmeter, and so forth.

The silicon supply unit 44 includes a silicon source 44A, a silicon supply line 44B and a fourth flow rate controller 44C.

The silicon source 44A is a tank which stores the silicon-containing compound aqueous solution therein. The silicon supply line 44B is configured to connect the silicon source 44A and the temperature control tank 47 and configured to supply the silicon-containing compound aqueous solution from the silicon source 44A into the temperature control tank 47.

The fourth flow rate controller 44C is provided at the silicon supply line 44B and configured to adjust a flow rate of the silicon-containing compound aqueous solution supplied to the temperature control tank 47. The fourth flow rate controller 44C is composed of an opening/closing valve, a flow rate control valve, a flowmeter, and so forth.

Further, the silicon-containing compound aqueous solution is supplied when generating a reserve liquid which is supplied when replacing the etching liquid completely.

The inner tub 45 has an open top, and the etching liquid is supplied to near the top thereof. In the inner tub 45, the lot (the multiplicity of substrates 8) is immersed in the etching liquid by the substrate elevating device 29, so that the etching processing is performed on the substrates 8. The inner tub 45 constitutes a substrate processing tub.

The outer tub 46 is provided around an upper portion of the inner tub 45 and has an open top. The etching liquid overflown from the inner tub 45 is introduced into the outer tub 46. Further, the reserve liquid, which is the phosphoric acid aqueous solution mixed with the silicon-containing compound aqueous solution, is supplied into the outer tub 46 from the temperature control tank 47. Further, the pure water is supplied into the outer tub 46 from the pure water supply unit 42. Furthermore, the SiO₂ precipitation inhibitor is also supplied into the outer tub 46 from the SiO₂ precipitation inhibitor supply unit 43. The SiO₂ precipitation inhibitor supplied into the outer tub 46 is mixed into the etching liquid within the outer tub 46 or mixed into the reserve liquid supplied from the temperature control tank 47. That is, the SiO₂ precipitation inhibitor is mixed into the phosphoric acid aqueous solution in the outer tub 46.

The outer tub 46 and the inner tub 45 are connected by a first circulation line 50. One end of the first circulation line 50 is connected to the outer tub 46, and the other end of the first circulation line 50 is connected to a processing liquid supply nozzle 49 provided within the inner tub 45.

The first circulation line 50 is provided with a first pump 51, a first heater 52 and a filter 53 in sequence from the outer tub 46 side. The etching liquid within the outer tub 46 is introduced into the inner tub 45 from the processing liquid supply nozzle 49 after a temperature thereof is increased by the first heater 52. The first heater 52 heats the etching liquid to be supplied into the inner tub 45 to a first preset temperature suitable for the etching processing.

By driving the first pump 51, the etching liquid is fed into the inner tub 45 from the outer tub 46 through the first circulation line 50. Further, the etching liquid is flown back into the outer tub 46 by being overflown from the inner tub 45. In this way, a circulation path 55 of the etching liquid is formed. That is, the circulation path 55 is formed by the outer tub 46, the first circulation line 50 and the inner tub 45. In the circulation path 55, the inner tub 45, the outer tub 46 and the first heater 52 are provided in sequence from an upstream side of the circulation path 55.

In the temperature control tank 47, the phosphoric acid aqueous solution supplied from the phosphoric acid aqueous solution supply unit 40 and the silicon-containing compound aqueous solution supplied from the silicon supply unit 44 are mixed to produce the reserve liquid, and this reserve liquid is stored in the temperature control tank 47. That is, in the temperature control tank 47, the silicon-containing compound aqueous solution is mixed into the phosphoric acid aqueous solution before being supplied into the outer tub 46 (circulation path 55).

Connected to the temperature control tank 47 is a second circulation line 60 through which the reserve liquid within the temperature control tank 47 is circulated. Further, one end of a supply line 70 is connected to the temperature control tank 47, and the other end of the supply line 70 is connected to the outer tub 46. The temperature control tank 47 serves as a reserve tank which stores the reserve liquid therein. The temperature control tank 47 constitutes a mixing unit.

The second circulation line 60 is provided with a second pump 61 and a second heater 62. By driving the second pump 61 in a state that the second heater 62 is turned ON, the reserve liquid within the temperature control tank 47 is circulated with a temperature thereof increased. The second heater 62 heats the reserve liquid to a second preset temperature suitable for the etching processing. The second preset temperature may be equal to or different from the first preset temperature.

The supply line 70 is provided with a third pump 71 and a fifth flow rate controller 72. The fifth flow rate controller 72 is configured to adjust a flow rate of the reserve liquid supplied into the outer tub 46. The fifth flow rate controller 72 is composed of an opening/closing valve, a flow rate control valve, a flowmeter, and so forth.

The reserve liquid stored in the temperature control tank 47 is supplied into the outer tub 46 through the supply line 70 when replacing the whole or a part of the etching liquid.

The phosphoric acid aqueous solution drain unit 41 is configured to drain the etching liquid when replacing the whole or the part of the etching liquid used in the etching processing. The phosphoric acid aqueous solution drain unit 41 includes a drain line 41A, a sixth flow rate controller 41B and a cooling tank 41C.

The drain line 41A is connected to the first circulation line 50. The sixth flow rate controller 41B is provided at the drain line 41A and configured to adjust a drain amount of the etching liquid. The sixth flow rate controller 41B is composed of an opening/closing valve, a flow rate control valve, a flowmeter, and so forth. The cooling tank 41C temporarily stores therein and cools the etching liquid flown through the drain line 41A.

Further, opening/closing operations of the opening/closing valves and opening degrees of the flow rate control valves, which constitute the first to sixth flow rate controllers 40C to 41B, are changed as actuators (not shown) are operated based on signals from the control unit 100. That is, the opening/closing valves and the flow rate control valves constituting the first to sixth flow rate controllers 40C to 41B are controlled by the control unit 100.

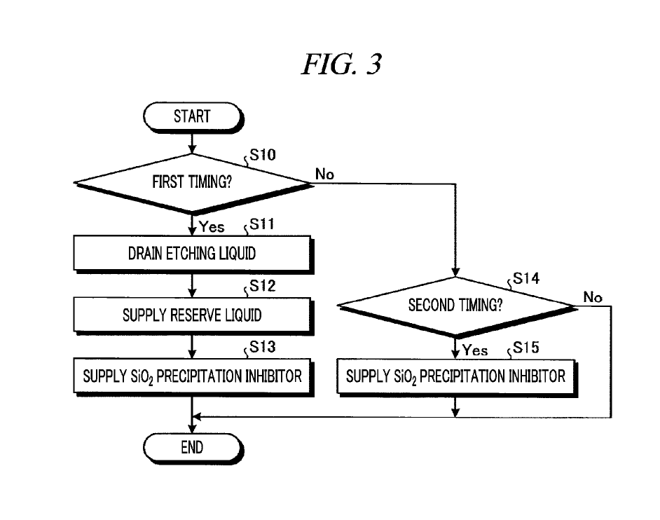

Now, a method of supplying the SiO₂ precipitation inhibitor in the substrate processing apparatus 1 according to the first exemplary embodiment will be explained with reference to FIG. 3. FIG. 3 is a flowchart for describing the method of supplying the SiO₂ precipitation inhibitor according to the first exemplary embodiment. Further, here, it is assumed that the silicon-containing compound aqueous solution is mixed in the phosphoric acid aqueous solution to be stored as the reserve liquid in the temperature control tank 47.

The substrate processing apparatus 1 determines whether it is a first timing (S10). The first timing is previously set and is a time when a part of the etching liquid is drained by the phosphoric acid aqueous solution drain unit 41 and the reserve liquid is supplied into the outer tub 46 from the temperature control tank 47. The substrate processing apparatus 1 determines whether it is the first timing based on, for example, an elapsed time of the etching processing.

When it is the first timing (S10: Yes), the substrate processing apparatus 1 drains the part of the etching liquid by the phosphoric acid aqueous solution drain unit 41 (S11).

After the draining of the etching liquid is completed, the substrate processing apparatus 1 supplies the reserve liquid to the outer tub 46 from the temperature control tank 47 and supplies the SiO₂ precipitation inhibitor to the outer tub 46 from the SiO₂ precipitation inhibitor supply unit 43. Accordingly, the SiO₂ precipitation inhibitor is mixed into the etching liquid (reserve liquid) in the outer tub 46. Further, a supply amount of the SiO₂ precipitation inhibitor is controlled such that a concentration of the SiO₂ precipitation inhibitor in the etching liquid falls within a predetermined range.

When it is not the first timing (S10: No), the substrate processing apparatus 1 determines whether it is a second timing (S14). The second timing is a time when the SiO₂ precipitation inhibitor is evaporated from the etching liquid and the concentration of the SiO₂ precipitation inhibitor in the etching liquid is decreased to below a predetermined concentration.

The substrate processing apparatus 1 determines whether it is the second timing based on, for example, the elapsed time of the etching processing. Further, the substrate processing apparatus 1 may measure the concentration of the SiO₂ precipitation inhibitor in the etching liquid and, based on this measured concentration, may determine whether it is the second timing.

When it is the second timing (S14: Yes), the substrate processing apparatus 1 supplies the SiO₂ precipitation inhibitor into the outer tub 46 from the SiO₂ precipitation inhibitor supply unit 43 (S15). Further, the supply amount of the SiO₂ precipitation inhibitor is controlled such that the concentration of the SiO₂ precipitation inhibitor in the etching liquid falls within the predetermined range.

If it is not the second timing (S14: No), the substrate processing apparatus 1 ends the current processing.

Further, the substrate processing apparatus 1 may make the determination upon whether it is the second timing before making the determination upon whether it is the first timing.

The substrate processing apparatus 1 generates the etching liquid in which the SiO₂ precipitation inhibitor is mixed into the phosphoric acid aqueous solution in the outer tub 46 and performs the etching processing on the substrates 8 by immerging the substrates 8 in the inner tub 45 into which the etching liquid is supplied. Accordingly, even if the silicon concentration of the etching liquid is increased, it is still possible to suppress the precipitation of the silicon oxide. Therefore, the precipitation of the silicon oxide can be suppressed while improving the selectivity for etching only the silicon nitride film of the substrate 8.

Furthermore, in the substrate processing apparatus 1, it may be possible to perform the etching processing by supplying an etching liquid without containing the SiO₂ precipitation inhibitor into the inner tub 45. In this case, if the silicon oxide is precipitated as the silicon concentration of the etching liquid not containing the SiO₂ precipitation inhibitor is increased, the SiO₂ precipitation inhibitor is added to the etching liquid, so that the etching processing is performed with the etching liquid containing the SiO₂ precipitation inhibitor.

### Second Exemplary Embodiment

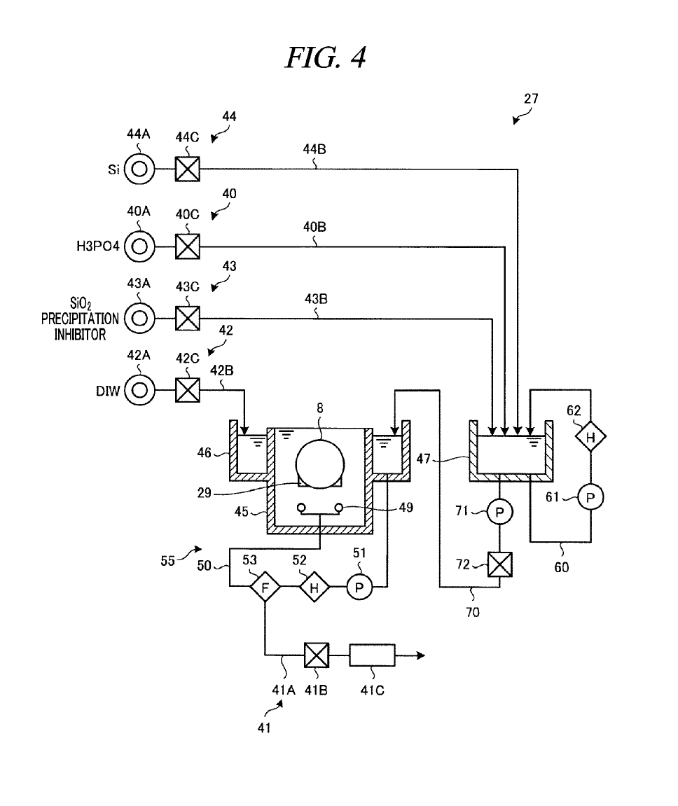

Now, a substrate processing apparatus 1 according to a second exemplary embodiment will be explained with reference to FIG. 4. FIG. 4 is a schematic block diagram illustrating a processing tub 27 for etching according to the second exemplary embodiment. Here, the same parts as those of the first exemplary embodiment will be assigned same reference numerals, and redundant description thereof will be omitted, while focusing on distinctive parts different from those of the first exemplary embodiment.

The SiO₂ precipitation inhibitor supply line 43 is configured to connect the SiO₂ precipitation inhibitor source 43A and the temperature control tank 47 and configured to supply the SiO₂ precipitation inhibitor from the SiO₂ precipitation inhibitor source 43A into the temperature control tank 47.

The SiO₂ precipitation inhibitor supplied into the temperature control tank 47 is uniformly mixed into the reserve liquid within the temperature control tank 47 by being circulated through the second circulation line 60 of the temperature control tank 47. The temperature control tank 47 stores therein the reserve liquid containing the SiO₂ precipitation inhibitor.

The reserve liquid stored in the temperature control tank 47 is supplied into the outer tub 46 through the supply line 70 and then supplied into the inner tub 45 as the etching liquid. In this way, the SiO₂ precipitation inhibitor is mixed into the reserve liquid (phosphoric acid aqueous solution) before being supplied into the circulation path 55. The temperature control tank 47 constitutes a mixing unit.

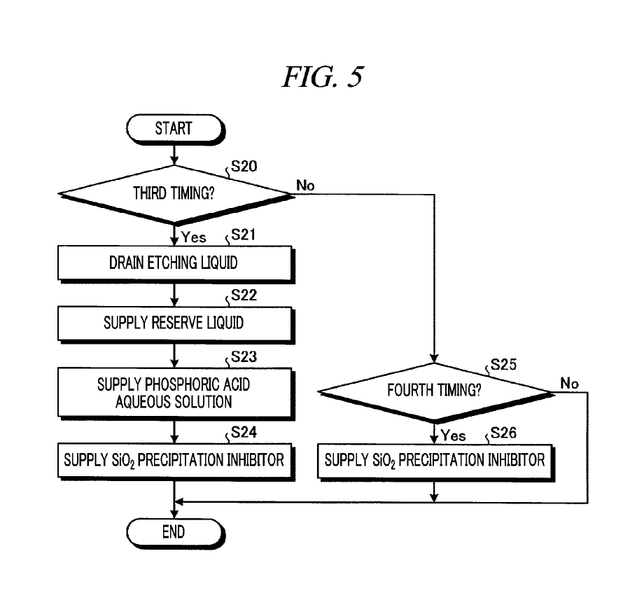

Now, a method of supplying the SiO₂ precipitation inhibitor in the substrate processing apparatus 1 according to the second exemplary embodiment will be described with reference to FIG. 5. FIG. 5 is a flowchart for describing the method of supplying the SiO₂ precipitation inhibitor according to the second exemplary embodiment. Here, it is assumed that the reserve liquid mixed with the SiO₂ precipitation inhibitor is previously stored in the temperature control tank 47.

The substrate processing apparatus 1 determines whether it is a third timing (S20). The third timing is a time when it is either the first timing or the second timing. That is, if it is either the first timing or the second timing, the substrate processing apparatus 1 determines that it is the third timing.

If it is the third timing (S20: Yes), the substrate processing apparatus 1 drains a part of the etching liquid by the phosphoric acid aqueous solution drain unit 41 (S21). After the draining of the etching liquid is finished, the substrate processing apparatus 1 supplies the reserve liquid mixed with the SiO₂ precipitation inhibitor into the outer tub 46 from the temperature control tank 47.

After the supply of the reserve liquid from the temperature control tank 47 is finished, the substrate processing apparatus 1 supplies the phosphoric acid aqueous solution into the temperature control tank 47 from the phosphoric acid aqueous solution supply unit 40 (S23), and supplies the SiO₂ precipitation inhibitor into the temperature control tank 47 from the SiO₂ precipitation inhibitor supply unit 43 (S24). Accordingly, in the temperature control tank 47, the reserve liquid containing the SiO₂ precipitation inhibitor mixed therein is newly generated.

When it is not the third timing (S20: No), the substrate processing apparatus 1 determines whether it is a fourth timing (S25). The fourth timing is a time when the SiO₂ precipitation inhibitor is evaporated from the reserve liquid within the temperature control tank 47 and, resultantly, the concentration of the SiO₂ precipitation inhibitor is reduced to below a predetermined concentration.

The substrate processing apparatus 1 determines whether it is the fourth timing based on, for example, a storage time of the reserve liquid or a heating time by the second heater 62. Further, the substrate processing apparatus 1 may measure the concentration of the SiO₂ precipitation inhibitor in the reserve liquid and, based on this measured concentration, may determine whether it is the fourth timing.

When it is the fourth timing (S25: Yes), the substrate processing apparatus 1 supplies the SiO₂ precipitation inhibitor into the temperature control tank 47 from the SiO₂ precipitation inhibitor supply unit 43 (S26). Further, a supply amount of the SiO₂ precipitation inhibitor is controlled such that the concentration of the SiO₂ precipitation inhibitor in the reserve liquid falls within a predetermined range.

If it is not the fourth timing (S25: No), the substrate processing apparatus 1 ends the current processing.

Further, the substrate processing apparatus 1 may make the determination upon whether it is the fourth timing before making the determination upon whether it is the third timing.

The substrate processing apparatus 1 according to the second exemplary embodiment generates the reserve liquid mixed with the SiO₂ precipitation inhibitor in the temperature control tank 47, and supplies the reserve liquid mixed with the SiO₂ precipitation inhibitor into the outer tub 46. That is, the substrate processing apparatus 1 mixes the SiO₂ precipitation inhibitor into the reserve liquid before the reserve liquid is supplied into the circulation path 55.

In the substrate processing apparatus 1, the SiO₂ precipitation inhibitor is previously mixed into the reserve liquid, and the reserve liquid in which the concentration of the SiO₂ precipitation inhibitor is uniform is supplied into the outer tub 46. In this way, by supplying into the outer tub 46 the reserve liquid in which the SiO₂ precipitation inhibitor is uniformly mixed, the non-uniform concentration of the SiO₂ precipitation inhibitor in the etching liquid within the outer tub 46 can be suppressed. Accordingly, the non-uniformity of the concentration of the SiO₂ precipitation inhibitor in the etching liquid supplied into the inner tub 45 can also be suppressed. Therefore, on the entire substrate 8, the precipitation of the silicon oxide can be suppressed while improving the selectivity for etching the nitride film.

### Third Exemplary Embodiment

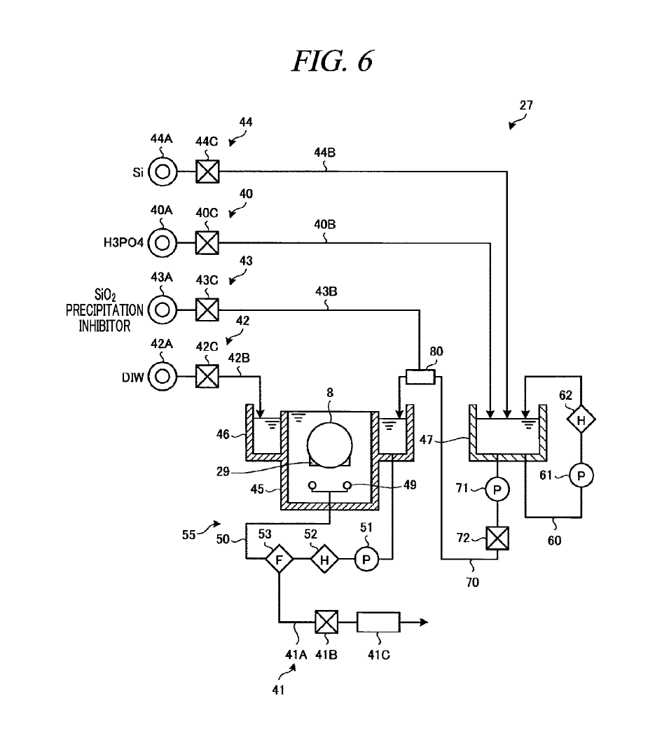

Now, a substrate processing apparatus 1 according to a third exemplary embodiment will be explained with reference to FIG. 6. FIG. 6 is a schematic block diagram illustrating a processing tub 27 for etching according to the third exemplary embodiment. Here, the same parts as those of the first exemplary embodiment will be assigned same reference numerals, and redundant description thereof will be omitted, while focusing on distinctive parts different from those of the first exemplary embodiment.

The processing tub 27 for mixing further includes a mixer 80. The mixer 80 is connected to the supply line 70 and the SiO₂ precipitation inhibitor supply line 43B.

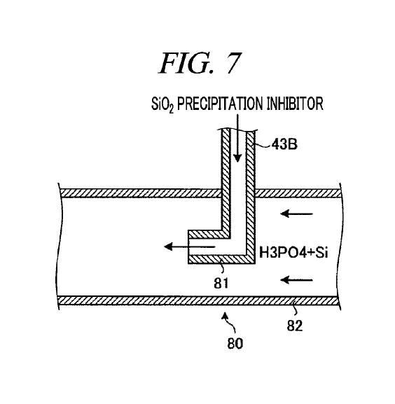

By way of example, the mixer 80 is implemented by a dual pipe in which one end of an inner pipe 81 is opened within an outer pipe 82, as shown in FIG. 7. The other end of the inner pipe 81 is connected to the SiO₂ precipitation inhibitor supply line 43B. The outer pipe 82 is connected to the supply line 70. To elaborate, the mixer 80 is arranged at the supply line 70, and the outer pipe 82 constitutes a part of the supply line 70. FIG. 7 is a cross sectional view illustrating a schematic configuration of the mixer 80 according to the third exemplary embodiment. The mixer 80 mixes the SiO₂ precipitation inhibitor flown out from the inner pipe 81 into the reserve liquid (phosphoric acid aqueous solution) flowing in the outer pipe 82. The mixer 80 constitutes a mixing unit.

The inner pipe 81 is formed to have, for example, a spiral shape to allow the SiO₂ precipitation inhibitor flown out from the inner pipe 81 to be uniformly mixed into the reserve liquid flowing in the outer pipe 82. The mixer 80 mixes the SiO₂ precipitation inhibitor into the reserve liquid by generating a turbulence in the SiO₂ precipitation inhibitor flown out from the inner pipe 81. The reserve liquid in which the SiO₂ precipitation inhibitor is mixed by the mixer 80 is then supplied into the outer tub 46. That is, the SiO₂ precipitation inhibitor is mixed into the reserve liquid (phosphoric acid aqueous solution) before being supplied into the circulation path 55.

Further, the mixer 80 may mix the SiO₂ precipitation inhibitor into the reserve liquid by generating the turbulence in various ways. By way of non-limiting example, prominences and depressions may be provided on an inner wall of the outer pipe 82, and prominences and depressions may be provided on an inner wall or an outer wall of the inner pipe 81. Furthermore, the mixer 80 may be a static mixer.

In addition, in the mixer 80, the other end of the inner pipe 81 may be connected to the supply line 70, and the outer pipe 82 may be connected to the SiO₂ precipitation inhibitor supply line 43B.

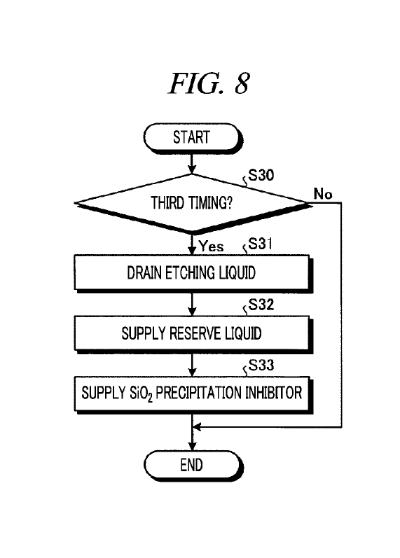

Now, a method of supplying the SiO₂ precipitation inhibitor in the substrate processing apparatus 1 according to the third exemplary embodiment will be described with reference to FIG. 8. FIG. 8 is a flowchart for describing the method of supplying the SiO₂ precipitation inhibitor according to the third exemplary embodiment.

The substrate processing apparatus 1 determines whether it is the third timing (S30). If it is the third timing (S30: Yes), the substrate processing apparatus 1 drains a part of the etching liquid by the phosphoric acid aqueous solution drain unit 41 (S31).

After the draining of the etching liquid is finished, the substrate processing apparatus 1 supplies the reserve liquid into the outer tub 46 from the temperature control tank 47 (S32), and supplies the SiO₂ precipitation inhibitor from the SiO₂ precipitation inhibitor supply unit 43 (S33). Accordingly, the SiO₂ precipitation inhibitor is flown out from the inner pipe 81 of the mixer 80, so that the reserve liquid in which the SiO₂ precipitation inhibitor is mixed is supplied into the outer tub 46.

Further, if the concentration of the SiO₂ precipitation inhibitor is decreased as the SiO₂ precipitation inhibitor in the etching liquid is evaporated, the mixer 80 may supply only the SiO₂ precipitation inhibitor into the outer tub 46 from the SiO₂ precipitation inhibitor supply unit 43.

In the substrate processing apparatus 1 according to the third exemplary embodiment, the reserve liquid mixed with the SiO₂ precipitation inhibitor by the mixer 80 is supplied into the outer tub 46. To elaborate, the substrate processing apparatus 1 mixes the SiO₂ precipitation inhibitor into the reserve liquid by generating the turbulence through the mixer 80, and supplies into the outer tub 46 the reserve liquid in which the SiO₂ precipitation inhibitor is uniformly mixed. In this way, by supplying into the outer tub 46 the reserve liquid in which the SiO₂ precipitation inhibitor is uniformly mixed, the non-uniform concentration of the SiO₂ precipitation inhibitor in the etching liquid within the outer tub 46 can be suppressed. Accordingly, difference in the concentration of the SiO₂ precipitation inhibitor in the etching liquid supplied into the inner tub 45 can be suppressed from being generated. Therefore, on the entire substrate 8, the precipitation of the silicon oxide can be suppressed while improving the selectivity for etching the nitride film.

### Fourth Exemplary Embodiment

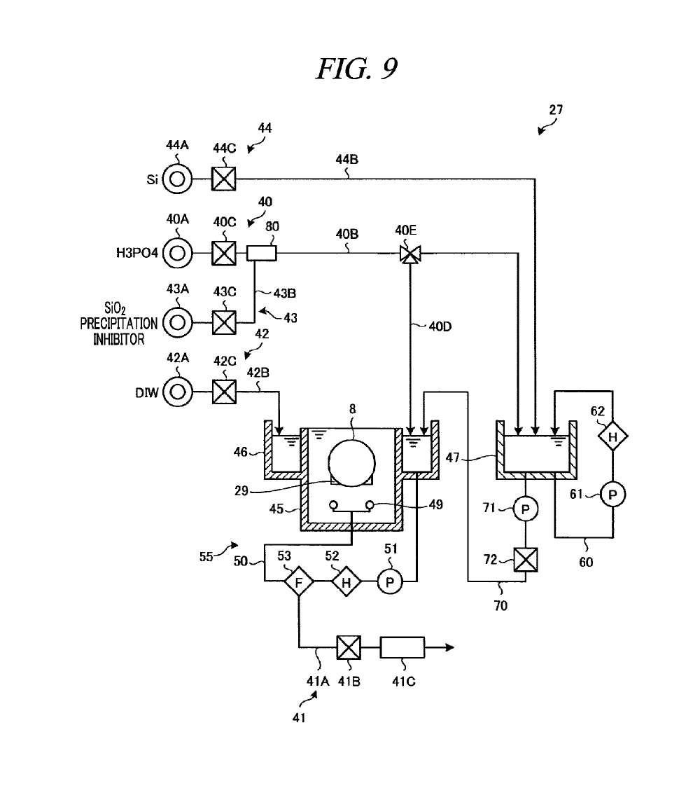

Now, a substrate processing apparatus 1 according to a fourth exemplary embodiment will be explained with reference to FIG. 9. FIG. 9 is a schematic block diagram illustrating a processing tub 27 for etching according to the fourth exemplary embodiment. Here, the same parts as those of the third exemplary embodiment will be assigned same reference numerals, and redundant description thereof will be omitted, while focusing on distinctive parts different from those of the third exemplary embodiment.

The phosphoric acid aqueous solution supply unit 40 is further equipped with a branch line 40D and a switching valve 40E.

The branch line 40D is connected to the phosphoric acid aqueous solution supply line 40B via the switching valve 40E. The branch line 40D is configured to connect the phosphoric acid aqueous solution supply line 40B and an outer tub 46.

A mixer 80 is connected to the phosphoric acid aqueous solution supply line 40B to be located closer to the phosphoric acid aqueous solution source 40A than to the switching valve 40E, and also connected to the SiO₂ precipitation inhibitor supply line 43B.

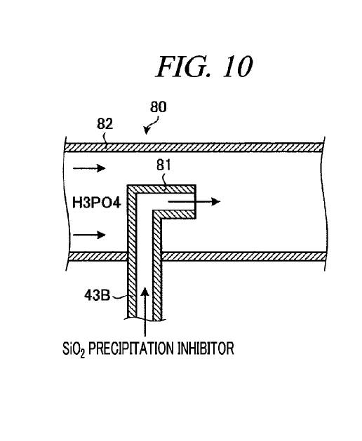

By way of example, the mixer 80 is implemented by a dual pipe in which one end of an inner pipe 81 is opened within an outer pipe 82, as shown in FIG. 10. The other end of the inner pipe 81 is connected to the SiO₂ precipitation inhibitor supply line 43B. The outer pipe 82 is connected to the phosphoric acid aqueous solution supply line 40B and constitutes a part of the phosphoric acid aqueous solution supply line 40B. FIG. 10 is a cross sectional view illustrating a schematic configuration of the mixer 80 according to the fourth exemplary embodiment. The mixer 80 mixes the SiO₂ precipitation inhibitor flown out from the inner pipe 81 into the phosphoric acid aqueous solution flowing in the outer pipe 82.

The inner pipe 81 is formed to have, for example, a spiral shape to allow the SiO₂ precipitation inhibitor flown out from the inner pipe 81 to be uniformly mixed into the phosphoric acid aqueous solution flowing in the outer pipe 82. The mixer 80 mixes the SiO₂ precipitation inhibitor into the phosphoric acid aqueous solution by generating a turbulence in the SiO₂ precipitation inhibitor flown out from the inner pipe 81.

The phosphoric acid aqueous solution in which the SiO₂ precipitation inhibitor is mixed by the mixer 80 is then supplied into the outer tub 46. That is, the SiO₂ precipitation inhibitor is mixed into the phosphoric acid aqueous solution before being supplied into the circulation path 55.

Further, the mixer 80 may mix the SiO₂ precipitation inhibitor into the phosphoric acid aqueous solution by generating the turbulence in various ways. By way of non-limiting example, prominences and depressions may be provided on an inner wall of the outer pipe 82, and prominences and depressions may be provided on an inner wall or an outer wall of the inner pipe 81. Furthermore, the mixer 80 may be a static mixer.

In addition, in the mixer 80, the other end of the inner pipe 81 may be connected to the phosphoric acid aqueous solution supply line 40B, and the outer pipe 82 may be connected to the SiO₂ precipitation inhibitor supply line 43B.

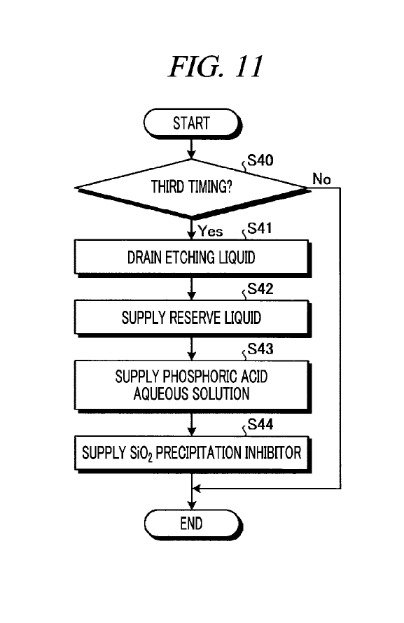

Now, a method of supplying the SiO₂ precipitation inhibitor in the substrate processing apparatus 1 according to the fourth exemplary embodiment will be described with reference to FIG. 11. FIG. 11 is a flowchart for describing the method of supplying the SiO₂ precipitation inhibitor according to the fourth exemplary embodiment.

The substrate processing apparatus 1 determines whether it is the third timing (S40). If it is the third timing (S40: Yes), the substrate processing apparatus 1 drains a part of the etching liquid by the phosphoric acid aqueous solution drain unit 41 (S41).

After the draining of the etching liquid is finished, the substrate processing apparatus 1 supplies the reserve liquid into the outer tub 46 from the temperature control tank 47 (S42).

The substrate processing apparatus 1 supplies the phosphoric acid aqueous solution from the phosphoric acid aqueous solution supply unit 40 into the outer tub 46 via the branch line 40D (S43), and supplies the SiO₂ precipitation inhibitor from the SiO₂ precipitation inhibitor supply unit 43. Accordingly, the SiO₂ precipitation inhibitor is supplied into the outer tub 46 after being mixed with the phosphoric acid aqueous solution of the room temperature by the mixer 80.

If it is not the third timing (S40: No), the substrate processing apparatus 1 ends the current processing.

Further, the mixer 80 may supply the SiO₂ precipitation inhibitor into the outer tub 46 from the inner pipe 81 in a state that the phosphoric acid aqueous solution is not supplied from the phosphoric acid aqueous solution source 40A. Further, the substrate processing apparatus 1 may supply the phosphoric acid aqueous solution mixed with the SiO₂ precipitation inhibitor by the mixer 80 into the supply line 70 or into the temperature control tank 47.

In the substrate processing apparatus 1 according to the fourth exemplary embodiment, the SiO₂ precipitation inhibitor is mixed, by the mixer 80, into the phosphoric acid aqueous solution flowing in the phosphoric acid aqueous solution supply line 40B.

A boiling point of the SiO₂ precipitation inhibitor is lower than a temperature of the reserve liquid within the temperature control tank 47 or a temperature of the etching liquid within the outer tub 46. Accordingly, if the SiO₂ precipitation inhibitor is directly mixed into the reserve liquid or the etching liquid, there is a concern that a part of the SiO₂ precipitation inhibitor may be evaporated before being mixed with these liquids.

Since the phosphoric acid aqueous solution flowing in the phosphoric acid aqueous solution supply line 40B is of the room temperature without being heated, the temperature of the phosphoric acid aqueous solution is lower than the temperature of the reserve liquid within the temperature control tank 47 or the temperature of the etching liquid within the outer tub 46. In the substrate processing apparatus 1 according to the fourth exemplary embodiment, by mixing the SiO₂ precipitation inhibitor into the phosphoric acid aqueous solution of the room temperature (which is lower) and supplying the room-temperature phosphoric acid aqueous solution mixed with the SiO₂ precipitation inhibitor into the outer tub 46, the evaporation of the SiO₂ precipitation inhibitor can be suppressed.

### Modification Example

In a substrate processing apparatus 1 according to a modification example, by connecting the supply line 70 to the inner tub 45, the reserve liquid can be supplied into the inner tub 45 from the temperature control tank 47.

Further, in the substrate processing apparatus 1 according to the modification example, by connecting the silicon supply line 44B to the outer tub 46, the silicon-containing compound aqueous solution can be supplied into the outer tub 46.

Though the above-described substrate processing apparatus 1 is configured to process the multiplicity of substrates 8 at the same time, it may be configured as a single-wafer processing apparatus configured to process the substrates 8 one by one.

Further, in the above-described substrate processing apparatus 1, as the method of supplying the SiO₂ precipitation inhibitor, a part of the etching liquid is first drained by the phosphoric acid aqueous solution drain unit 41. However, the exemplary embodiments are not limited thereto, and it may be possible to perform the draining of the etching liquid while supplying the reserve liquid, the phosphoric acid aqueous solution or the SiO₂ precipitation inhibitor.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a substrate processing tub;
a phosphoric acid processing liquid supply unit configured to supply a phosphoric acid processing liquid used in an etching processing in the substrate processing tub;
a circulation path configured to circulate the phosphoric acid processing liquid supplied into the substrate processing tub;
a SiO₂ precipitation inhibitor supply unit configured to supply a SiO₂ precipitation inhibitor into the circulation path; and
a mixing unit configured to mix a silicon-containing compound into the phosphoric acid processing liquid before the phosphoric acid processing liquid is supplied into the circulation path.

2. A substrate processing apparatus, comprising:
a substrate processing tub;
a phosphoric acid processing liquid supply unit configured to supply a phosphoric acid processing liquid used in an etching processing in the substrate processing tub;
a SiO₂ precipitation inhibitor supply unit configured to supply a SiO₂ precipitation inhibitor;
a circulation path configured to circulate the phosphoric acid processing liquid supplied into the substrate processing tub; and
a mixing unit configured to mix the SiO₂ precipitation inhibitor into the phosphoric acid processing liquid before the phosphoric acid processing liquid is supplied into the circulation path.

3. The substrate processing apparatus of claim 2,
wherein the mixing unit is implemented by a reserve tank configured to mix and store the phosphoric acid processing liquid supplied from the phosphoric acid processing liquid supply unit and the SiO₂ precipitation inhibitor supplied from the SiO₂ precipitation inhibitor supply unit.

4. The substrate processing apparatus of claim 2, further comprising:
a reserve tank configured to mix and store a silicon-containing compound into the phosphoric acid processing liquid supplied from the phosphoric acid processing liquid supply unit,
wherein the mixing unit is configured to mix the SiO₂ precipitation inhibitor into the phosphoric acid processing liquid supplied from the reserve tank.

5. The substrate processing apparatus of claim 2,
wherein the mixing unit is configured to mix the SiO₂ precipitation inhibitor into the phosphoric acid processing liquid of a room temperature.

6. The substrate processing apparatus of claim 4,
wherein the mixing unit is configured to mix the SiO₂ precipitation inhibitor into the phosphoric acid processing liquid by generating a turbulence in the phosphoric acid processing liquid and a turbulence in the SiO₂ precipitation inhibitor.

7. A substrate processing method, comprising:
mixing a SiO₂ precipitation inhibitor into a phosphoric acid processing liquid before the phosphoric acid processing liquid is supplied into a circulation path through which the phosphoric acid processing liquid supplied into a substrate processing tub is circulated; and
supplying the phosphoric acid processing liquid mixed with the SiO₂ precipitation inhibitor into the circulation path.

8. The substrate processing method of claim 7,
wherein, in the mixing of the SiO₂ precipitation inhibitor, the SiO₂ precipitation inhibitor is mixed into the phosphoric acid processing liquid of a room temperature.

9. The substrate processing method of claim 7,
wherein, in the mixing of the SiO₂ precipitation inhibitor, the SiO₂ precipitation inhibitor is mixed into the phosphoric acid processing liquid by generating a turbulence in the phosphoric acid processing liquid and a turbulence in the SiO₂ precipitation inhibitor.
